(19) United States
(12) Patent Application Publication
(10) Pub. No.: US 2012/0242415 A1
(43) Pub. Date: Sep. 27, 2012

(54) PLL CIRCUIT AND CONTROL METHOD THEREOF

(75) Inventor: Yuki Tsuda, Kawasaki-Shi (JP)

(73) Assignee: KABUSHIKI KAISHA TOSHIBA, Tokyo (JP)

(21) Appl. No.: 13/251,345

(22) Filed: Oct. 3, 2011

(30) Foreign Application Priority Data
Mar. 25, 2011 (JP) 2011-068722

(51) Int. Cl. H03L 7/07

(52) U.S. Cl. 331/27

(57) ABSTRACT

A PLL circuit has a voltage control oscillator, a rough-adjusting loop part and a fine-adjusting loop part. The rough-adjusting loop part configured to perform a rough adjustment to the frequency of the oscillating signal based on a frequency-setting signal. The fine-adjusting loop part performs a fine adjustment to the frequency of the oscillating signal after the rough adjustment by the rough-adjusting loop part. The fine-adjusting loop part includes a phase comparator configured to detect a phase difference between the frequency-divided signal obtained by frequency-dividing the oscillating signal at the frequency divider and the reference signal while a switched state of each of the first switching parts at a moment of the completion of the rough adjustment at the rough-adjusting loop part remains unchanged.

### CROSS REFERENCE TO RELATED APPLICATIONS

This application is based upon and claims the benefit of priority from the prior Japanese Patent Application No. 2011-68722, filed on Mar. 25, 2011, the entire contents of which are incorporated herein by reference.

### FIELD

Embodiments of the present invention relate a PLL circuit equipped with a voltage control oscillator.

### BACKGROUND

A PLL circuit that outputs accurate oscillating signals (clock signals) is an essential part of a digital circuit. The PLL circuit performs feedback control so as to lock the frequency of oscillating signals of a voltage control oscillator (VCO) at a desired oscillating frequency.

In order to improve the phase noise characteristics of a VCO require, it is necessary to lower sensibility to a frequency change due to the change in control voltage of the VCO. Therefore, in some cases, the VCO is provided with a fixed capacitor having a fixed capacitance, and a switch for switching the fixed capacitor between active and inactive, in addition to a variable capacitor having a capacitance variable by a control voltage,

However, an improper fixed capacitor is selected if the switching cannot be correctly performed due to the waveform rounding of oscillating signals, influence of noises, etc. This may result in large deviation of the frequency of oscillating signals, and there is a likelihood which cannot autonomously recover to the original frequency.

### BRIEF DESCRIPTION OF THE DRAWINGS

FIG. 1 is a block diagram schematically showing the configuration of a PLL circuit according to the present embodiment;

FIGS. 2(a) and 2(b) are circuit diagrams of a VCO 2 and a variable capacitance part 13, respectively;

FIGS. 3(a) and 3(b) are conceptual views of operations of a rough-adjusting loop part 3 and a fine-adjusting loop part 4, respectively; and

FIG. 4 is a flow chart showing an operation of the PLL circuit according to the present embodiment.

### DETAILED DESCRIPTION

Embodiments will now be explained with reference to the accompanying drawings.
1. A PLL circuit has:

a voltage control oscillator configured to control a frequency of an oscillating signal based on a control signal;

a rough-adjusting loop part configured to perform a rough adjustment to the frequency of the oscillating signal based on a frequency-setting signal;

a fine-adjusting loop part configured to perform a fine adjustment to the frequency of the oscillating signal after the rough adjustment by the rough-adjusting loop part; and

a loop control part configured to operate either the rough- or fine-adjusting loop part,

wherein the voltage control oscillator includes:

a variable capacitor having a capacitance variable with the control signal;

a plurality of fixed capacitors each having a fixed capacitance and being connectable in parallel to the variable capacitor; and

a plurality of first switching parts each connected in series to a corresponding fixed capacitor among the a plurality of fixed capacitors and configured to switch whether or not to connect in parallel the corresponding fixed capacitor to the variable capacitor,

the rough-adjusting loop part includes:

a switching-information storing part configured to store switching information for the first switching parts;

a switching-information setting part configured to set switching information for the first switching parts;

a frequency divider configured to generate a frequency-divided signal by frequency-dividing the oscillating signal of the voltage control oscillator adjusted based on the switching information set by the switching-information setting part for the first switching parts;

an oscillating-frequency adjusting part configured to instruct the switching-information setting part to set again the switching information based on a result of comparing a frequency of the frequency-divided signal with a frequency of a reference signal; and

a comparator configured to generate differential information between the switching information set by the switching-information setting part and the switching information stored in the switching-information storing part, and to inform the loop control part of completion of the rough adjustment if the differential information belongs in a specific threshold range whereas instruct the switching-information setting part to set again the switching information if the differential information is out of the threshold range, and

the fine-adjusting loop part includes:

a phase comparator configured to detect a phase difference between the frequency-divided signal obtained by frequency-dividing the oscillating signal at the frequency divider and the reference signal while a switched state of each of the first switching parts at a moment of the completion of the rough adjustment at the rough-adjusting loop part remains unchanged;

a charge pump configured to generate a voltage signal in accordance with the phase difference; and

a loop filter configured to remove noises included in the voltage signal to generate the control signal for controlling the capacitance of the variable capacitor.

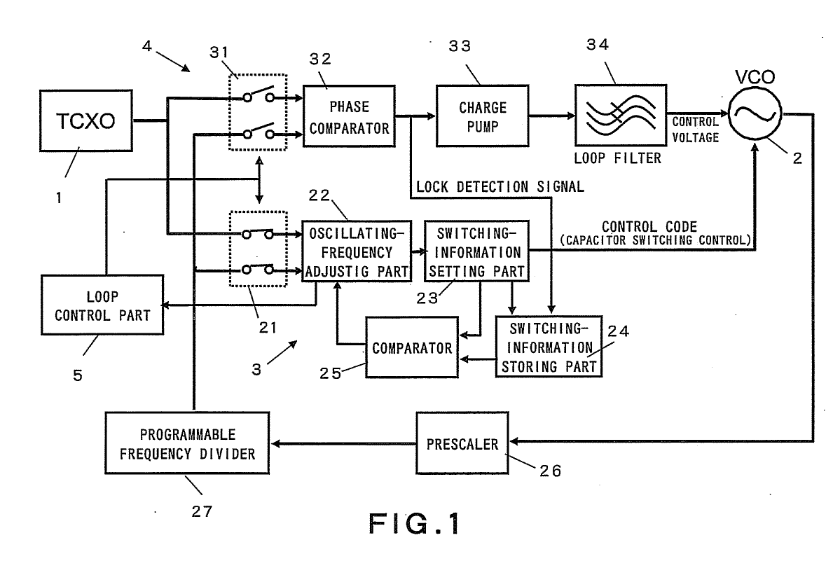

FIG. 1 is a block diagram schematically showing the configuration of a PLL circuit according to the present embodiment. The PLL circuit of FIG. 1 is provided with a local oscillator (TCXO) 1, a voltage control oscillator (VCO) 2, a rough-adjusting loop part 3, a fine-adjusting loop part 4, and a loop control part 5.

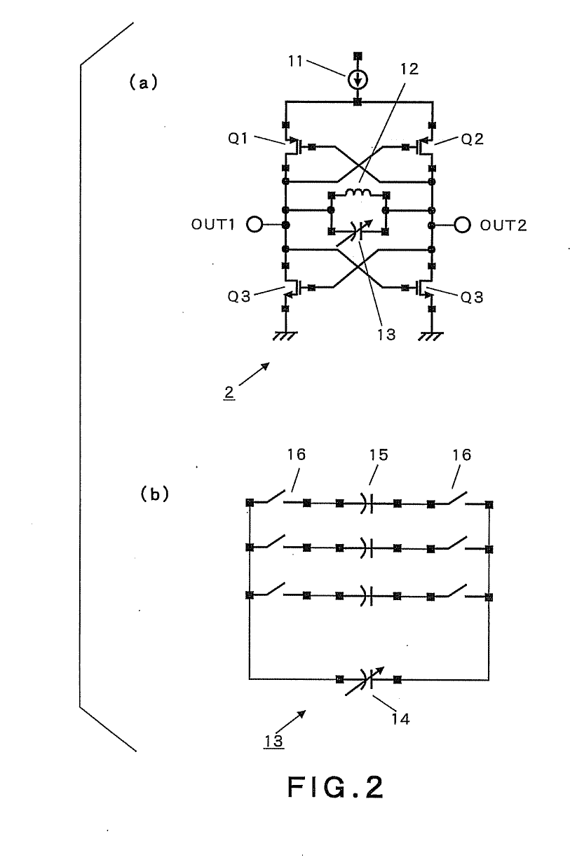

The VCO 2 is composed of a circuit such as shown in FIG. 2(a). The VCO 2 of FIG. 2(a) has a current source 11, transistors Q1 and Q2 for switching whether or not to flow the current from the current source 11 in accordance with voltage levels at output terminals OUT1 and OUT2, transistors Q3 and Q4 either of which is turned on in accordance with the voltage levels at the output terminals OUT1 and OUT2, and an inductor 12 and a variable capacitance part 13 connected in parallel between the output terminals OUT1 and OUT2. The VCO 2 of FIG. 2(a) varies the frequency of an oscillating signal by adjusting the capacitance of the variable capacitance part 13 with an external control signal.

The variable capacitance part 13 is composed of a circuit such as shown in FIG. 2(b). The variable capacitance part 13 of FIG. 2(b) has a variable capacitance diode 14 having a capacitance variable with a control signal, a plurality of fixed capacitors 15 each being connectable in parallel to the variable capacitance diode 14, and a plurality of first switching parts 16 each for switching whether or not to connect the corresponding fixed capacitor 15 in parallel to the variable capacitance diode 14.

There are three fixed capacitors 15 in FIG. 2(b). However, this is just an example. Any number of two or more fixed capacitors 15 can be provided. The fixed capacitors 15 have the equivalent fixed capacitance. The first switching parts 16 are separately turned on or off. Therefore, fixed capacitors 15 series-connected to turned-on first switching parts 16 are only connected in parallel to the variable capacitance diode 14.

In this way, the variable capacitance part 13 of FIG. 2(b) controls the capacitance of the variable capacitance diode 14 to vary the total capacitance, via the first switching parts 16 each being turned on or off.

As described later, the first switching parts 16 are turned on or off for a rough adjustment to the frequency of an oscillating signal of the VCO 2. The capacitance of the variable capacitance diode 14 is varied for a fine adjustment to the frequency of the oscillating signal.

Returning to FIG. 1, the rough-adjusting loop part 3 has a second switching part 21, an oscillating-frequency adjusting part 22, a switching-information setting part 23, a switching-information storing part 24, a comparator 25, the VCO 2, a prescaler 26, and a programmable frequency divider 27. The VCO 2, the prescaler 26, and the programmable frequency divider 27 are shared by the rough- and fine-adjusting loop parts 3 and 4.

The second switching part 21 switches the operation of the rough-adjusting loop part 3 according to an instruction from the loop control part 5. The switching-information setting part 23 sets switching information for turning on or off the first switching parts 16 shown in FIG. 2(b).

The switching-information storing part 24 stores the switching information for the first switching parts 16. The oscillating-frequency adjusting part 22 compares a frequency of a frequency-divided signal generated by the programmable frequency divider 27 and that of a local oscillating signal generated by the local oscillator 1. The result of frequency comparison is transferred to the switching-information setting part 23. The switching-information setting part 23 turns on or off the first switching parts 16 based on the result of frequency comparison at the oscillating-frequency adjusting part 22. The operation continues until the completion of frequency comparison for a specific number of times or the oscillating frequency reaches a desired frequency, to search for optimum switching information.

The comparator 25 generates a differential value between new switching information set by the switching-information setting part 23 and the switching information stored in the switching-information storing part 24. The comparator 25 determines that the new switching information is appropriate if the differential value belongs in a predetermined threshold range. On the other hand, the comparator 25 determines that the new switching information is inappropriate if the differential value is out of the threshold range. The switching-information setting part 23 updates the switching information until the comparator 25 determines that the new switching information is appropriate.

Here, the switching information is used for instructing the first switching parts 16 to turn on of off. The switching information is referred to as a control code that is, for example, a bitstream of bits the number of which is the same as the number of the first switching parts 16. The value of each bit is set for turning on or off the corresponding first switching part 16. The switching-information setting part 23 continuously updates the control code until the comparator 25 determines that the new control code is an appropriate control code.

The switching-information storing part 24 stores the control code set in the switching-information setting part 23 at the moment of output of a lock detection signal from the fine-adjusting loop part 4, as described above. In this way, the switching information already stored in the switching-information storing part 24 is updated. The switching-information storing part 24 is composed of a latch circuit, register circuit, etc.

The fine-adjusting loop part 4 has a third switching part 31, a phase comparator 32, a charge pump 33, a loop filter 34, the VCO 2, the prescaler 26, and the programmable frequency divider 27.

The third switching part 31 switches the operation of the fine-adjusting loop part 4 according to an instruction from loop control part 5. The phase comparator 32 detects a phase difference between a frequency-divided signal output from the programmable frequency divider 27 and a local oscillating signal.

The charge pump 33 generates a voltage signal in accordance with the phase difference detected by the phase comparator 32. The loop filter 34 removes noises included in the voltage signal that is generated by the charge pump 33 to generate a control signal for controlling the variable capacitance diode 14 of FIG. 2(b). The prescaler 26 generates a frequency-divided signal that is the result of frequency division of an oscillating signal of the VCO 2 at a predetermined divider ratio. The programmable frequency divider 27 generates a frequency-divided signal that is the result of frequency division of the frequency-divided signal generated by the prescaler 26 at an externally specified divider ratio.

The loop control part 5 selects either the rough-adjusting loop part 3 or the fine-adjusting loop part 4 to turn on or off the second and third switching parts 21 and 31. The loop control part 5 selects the rough-adjusting loop part 3 at power-on or in an initial operation state. Moreover, the loop control part 5 detects the completion of the control by the rough-adjusting loop part 3 using a signal from the oscillating-frequency adjusting part 22 to switch the second and third switching parts 21 and 31.

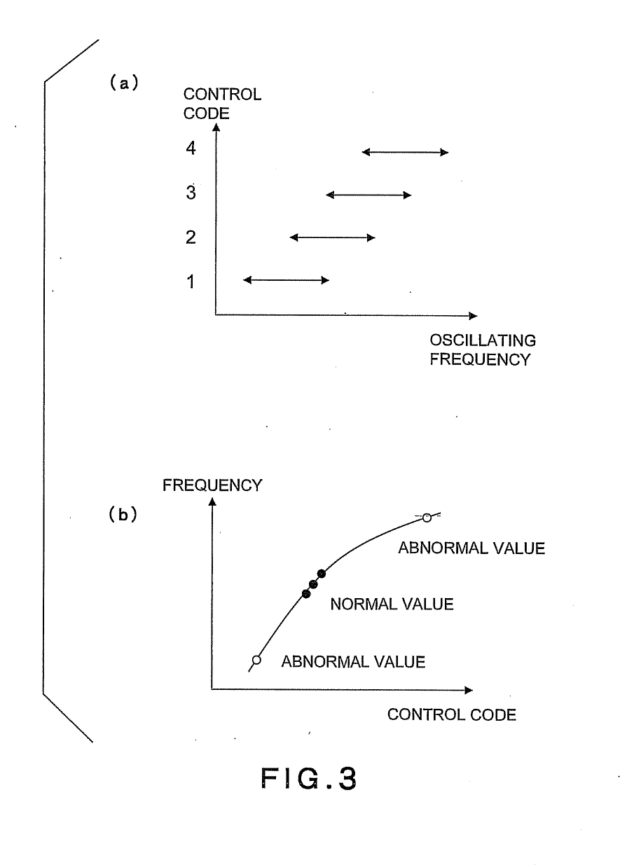

FIGS. 3(a) and 3(b) are conceptual views of the operations of the rough- and fine-adjusting loop parts 3 and 4, respectively. In FIG. 3(a), the absciss indicates the oscillating frequency, and the ordinate indicates the control code. In FIG. 3(b), the absciss indicates the control code and the ordinate indicates the oscillating frequency.

As shown in FIG. 3(a), the rough-adjusting loop part 3 changes the control code to vary the oscillating frequency in a stepwise fashion at a relatively large step.

FIG. 3(a) shows four left-right arrows each of which is selected by the corresponding control code. With the control code, the first switching parts 16 shown in FIG. 2(b) are separately turned on or off to vary the capacitance of the variable capacitance part 13, thus varying the oscillating frequency of the VCO 2.

The length of each left-right arrow in FIG. 3(a) indicates the range in which the frequency is variable. The adjoining left-right arrows overlap each other in the direction of frequency. This means that the same oscillating frequency can be set with a different control code. The reason for this is to adjust the oscillating frequency to the same frequency even if the control code is changed for some reason. With this adjustment, it is possible to avoid an undesirable situation that the oscillating frequency is shifted and cannot be returned to the original frequency.

The fine-adjusting loop part 4 performs a fine adjustment to the oscillating frequency with a control signal on the characteristic curve of the control code selected by the rough-adjusting loop part 3, as shown in FIG. 3(b). Accordingly, the fine-adjusting loop part 4 cannot vary the oscillating frequency largely but can perform a fine adjustment to the oscillating frequency.

In a normal operation, the oscillating frequency varies at a center region on the curve of FIG. 3(b). When the fine-adjusting loop part 4 operates erroneously for some reason, the oscillating frequency may be shifted to an end of the curve. Nevertheless, the shift occurs on the same curve, hence it is expected that the oscillating frequency is soon locked at a desired frequency in the center region.

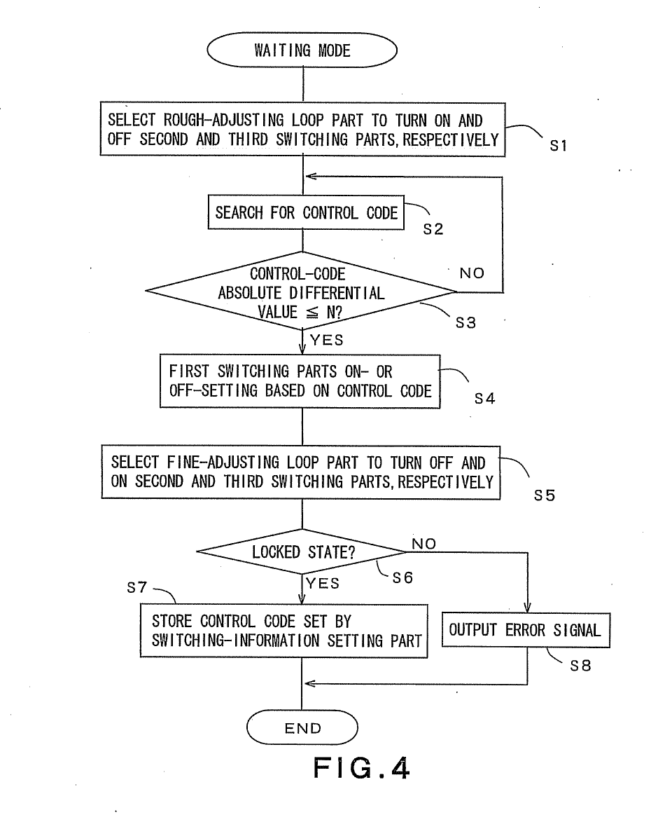

FIG. 4 is a flow chart showing an operation of the PLL circuit according to the present embodiment. The flow chart of FIG. 4 shows an operation in a waiting mode. Step Si and the succeeding steps start when a frequency-setting signal is externally input. The loop control part 5 selects the rough-adjusting loop part 3 to turn on the second switching part 21 and turn off the third switching part 31 (step Si). In this step, the on- or off-state of each first switching part 16 is set in accordance with the initial value of the control code. A preset value in the PLL circuit is always used as the initial value of the control code so that VCO 2 generates the same initial frequency. Next, the switching-information setting part 23 searches for a control code for turning on or off the first switching parts 16 in the variable capacitance part 13 (step S2). The control code is searched by changing the on- or off-state of each first switching part 16, for example.

In step S2, the following operation is repeated. Firstly, the VCO 2 varies the oscillating frequency based on a control code set by the switching-information setting part 23. Then, the oscillating-frequency adjusting part 22 compares a frequency-divided signal of the varied oscillating frequency and a local oscillating signal of the local oscillator 1. Based on the result of comparison, the switching-information setting part 23 sets a new control code for turning on or off the first switching parts 16 in the variable capacitance part 13. After the operation is repeated several times, the comparator 25 compares the new control code set by the switching-information setting part 23 with the control codes stored in the switching-information storing part 24 to generate a differential value. It is then determined whether the absolute value of the differential value is equal to or smaller than a specific value N (step S3). The value N can be set to any value in accordance with the oscillating frequency. If it is determined in step S3 that the absolute value is equal to or smaller than the specific value, the control code set by the switching-information setting part 23 is determined as an effective value and then, based on the control code, and the on- or off-states of the first switching parts 16 are set (step S4). There are several expectation values for the control code, as shown in FIG. 3(a). Nevertheless, a purpose here is to prevent an inappropriate control code from being selected, without searching for a more appropriate control code.

On the other hand, if the absolute value of the differential value is determined to be larger than the specific value in step S3, for instance if the control code has a different value for some reason, the process returns to step S2 to repeat the process from the beginning.

Next, the loop control part 5 selects the fine-adjusting loop part 4 to turn off the second switching part 21 and turn on the third switching part 31 (step S5). Through the switched the second and third switching parts 21 and 31, the phase comparator 32 in the fine-adjusting loop part 4 acquires a frequency-divided signal obtained by frequency division of an oscillating signal of the VCO 2 from the programmable frequency divider 27 and also an oscillating signal from the local oscillator 1 and detects a phase difference between the frequency-divided signal and the oscillating signal. Then, the charge pump 33 generates a voltage signal in accordance with the detected phase difference. The voltage signal undergoes noise removal and then conversion into a control signal, by the loop filter 34. The control signal is used for adjustment to the capacitance of the variable capacitance diode 14 of VCO 2 shown in FIG. 2(b).

As a result of control by the fine-adjusting loop part 4, when a phase difference detected by the phase comparator 32 becomes equal to or smaller than a specific value (such as almost zero), the PLL circuit enters in the locked state that indicates the completion of fine adjustment to the oscillating frequency. Then, the phase comparator 32 determines whether the PLL circuit is in the locked state (step S6). If it is in the locked state, the phase comparator 32 supplies a lock detection signal to the switching-information storing part 24 in the rough-adjusting loop part 3. When the lock detection signal is input, the switching-information storing part 24 stores a control code that has been set by the switching-information setting part 23 up to this moment (step S7). The control code stored in the switching-information storing part 24 is not updated until power-on or an initial operation thereafter. Therefore, the on- or off-states of the first switching parts 16 remain unchanged.

On the other hand, if the PLL circuit does not enter in the locked state no matter how much time passes, the phase comparator 32 outputs an error signal (step S8).

There are several techniques for the process to be performed when the error signal is output. Although not described in detail, an unlocked state may be informed to a system equipped with the PLL circuit of the present embodiment to repeat again an initial operation or to inform occurrence of a fault.

As described above, in the present embodiment, firstly, the rough-adjusting loop part 3 adjusts a control code for setting the on- or off-states of the first switching parts 16 connected in series to the fixed capacitors 15 in the VCO 2, to perform a rough adjustment to the oscillating frequency. When the rough adjustment is complete, the on- or off-settings of the first switching parts 16 remain unchanged. Next, the fine-adjusting loop part 4 adjusts the capacitance of the variable capacitance diode 14 in the VCO 2 based on a phase difference detected by the phase comparator 32, to perform a fine adjustment to the oscillating frequency. When the phase comparator 32 outputs a lock detection signal, the switching-information storing part 24 stores a control code held by the rough-adjusting loop part 3. Accordingly, an appropriate control code can be quickly set for the rough-adjusting loop part 3 to perform the next operation. Moreover, the fine-adjusting loop part 4 performs a fine adjustment after the rough-adjusting loop part 3 sets a control code. Therefore, even if the control code largely varies for some reason during the operation of the fine-adjusting loop part 4, there is no risk of change in the control code set by the rough-adjusting loop part 3. Accordingly, the PLL circuit can be quickly locked at a desired oscillating frequency, with almost no problem of an unlocked state due to large deviation of a control signal.

In FIG. 1, the prescaler 26 and the programmable frequency divider 27 are used for frequency division of an oscillating signal generated by the VCO 2. These parts may be integrated into a single frequency divider for frequency division.

Moreover, some components of the rough-adjusting loop part 3 and the fine-adjusting loop part 4 shown in FIG. 1 may be integrated into a single component. For example, any of the oscillating-frequency adjusting part 22, the switching-information setting part 23, the switching-information storing part 24, and the comparator 25 in the rough-adjusting loop part 3 may be integrated into a single component.

Furthermore, the internal configuration of the VCO 2 shown in FIG. 2(a) is just an example. The VCO 2 can take any form concerning the circuit configuration as long as it has the variable capacitance part 13 such as shown in FIG. 2(b).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A PLL circuit comprising:
a voltage control oscillator configured to control a frequency of an oscillating signal based on a control signal;
a rough-adjusting loop part configured to perform a rough adjustment to the frequency of the oscillating signal based on a frequency-setting signal;
a fine-adjusting loop part configured to perform a fine adjustment to the frequency of the oscillating signal after the rough adjustment by the rough-adjusting loop part; and
a loop control part configured to operate either the rough- or fine-adjusting loop part,
wherein the voltage control oscillator comprises:
a variable capacitor having a capacitance variable with the control signal;
a plurality of fixed capacitors each having a fixed capacitance and being connectable in parallel to the variable capacitor; and
a plurality of first switching parts each connected in series to a corresponding fixed capacitor among the a plurality of fixed capacitors and configured to switch whether or not to connect in parallel the corresponding fixed capacitor to the variable capacitor,
the rough-adjusting loop part comprises:
a switching-information storing part configured to store switching information for the first switching parts;
a switching-information setting part configured to set switching information for the first switching parts;
a frequency divider configured to generate a frequency-divided signal by frequency-dividing the oscillating signal of the voltage control oscillator adjusted based on the switching information set by the switching-information setting part for the first switching parts;
an oscillating-frequency adjusting part configured to instruct the switching-information setting part to set again the switching information based on a result of comparing a frequency of the frequency-divided signal with a frequency of a reference signal; and
a comparator configured to generate differential information between the switching information set by the switching-information setting part and the switching information stored in the switching-information storing part, and to inform the loop control part of completion of the rough adjustment if the differential information belongs in a specific threshold range whereas instruct the switching-information setting part to set again the switching information if the differential information is out of the threshold range, and
the fine-adjusting loop part comprises:
a phase comparator configured to detect a phase difference between the frequency-divided signal obtained by frequency-dividing the oscillating signal at the frequency divider and the reference signal while a switched state of each of the first switching parts at a moment of the completion of the rough adjustment at the rough-adjusting loop part remains unchanged;
a charge pump configured to generate a voltage signal in accordance with the phase difference; and
a loop filter configured to remove noises included in the voltage signal to generate the control signal for controlling the capacitance of the variable capacitor.

2. The PLL circuit claimed in claim 1, wherein the comparator generates the differential information when the oscillating-frequency adjusting part has performed frequency adjustment to the frequency-divided signal for a predetermined number of times or when a difference in frequency between the frequency-divided signal and the reference signal becomes equal to or smaller than a predetermined value.

3. The PLL circuit claimed in claim 1, wherein the comparator informs the loop control part of the completion of the rough adjustment without a search for an optimum frequency for the frequency-divided signal if the differential information belongs in the threshold range.

4. The PLL circuit claimed in claim 1, wherein the oscillating-frequency adjusting part compares again the frequency of the frequency-divided signal with the frequency of the reference signal when the comparator determines that the differential information is out of the threshold range.

5. The PLL circuit claimed in claim 1, wherein the loop control part selects the rough-adjusting loop part in case of power-on or an initial operation and then determines a timing to operate the fine-adjusting loop part based on information from the oscillating-frequency adjusting part.

6. The PLL circuit claimed in claim 1, wherein the loop control part exclusively switches the rough- and fine-adjusting loop parts.

7. The PLL circuit claimed in claim 1 further comprising:
a second switching part configured to switch whether or not to supply the frequency-divided signal and the reference signal to the oscillating-frequency adjusting part; and
a third switching part configured to switch whether or not to supply the frequency-divided signal and the reference signal to the phase comparator,
wherein the loop control part performs switching control of the second and third switching parts.

8. The PLL circuit claimed in claim 1, wherein the fine-adjusting loop part performs the fine adjustment using a switched state of the first switching parts at a moment of the completion of the rough adjustment even if the control signal varies during the fine adjustment.

9. The PLL circuit claimed in claim 1, wherein the phase comparator outputs a lock detection signal indicating that the fine-adjusting loop part is in a locked state when the phase difference becomes equal to or smaller than a specific value, and
the switching-information storing part stores the switching information already set by the switching-information setting part, based on the lock detection signal.

10. The PLL circuit claimed in claim 1, wherein the switching-information setting part is configured to set any one of a plurality of pieces of switching information, neighboring two or more of the pieces of switching information being set so that variable ranges of an oscillating frequency is overlapped to each other.

11. A method of controlling a PLL circuit including:
a voltage control oscillator configured to control a frequency of an oscillating signal based on a control signal;
a rough-adjusting loop part configured to perform a rough adjustment to the frequency of the oscillating signal based on a frequency-setting signal;
a fine-adjusting loop part configured to perform a fine adjustment to the frequency of the oscillating signal after the rough adjustment by the rough-adjusting loop part; and
a loop control part configured to operate either the rough- or fine-adjusting loop part;
wherein the voltage control oscillator has:
a variable capacitor having a capacitance variable with the control signal;
a plurality of fixed capacitors each having a fixed capacitance and being connectable in parallel to the variable capacitor; and
a plurality of first switching parts each connected in series to a corresponding fixed capacitor among the a plurality of fixed capacitors and configured to switch whether or not to connect in parallel the corresponding fixed capacitor to the variable capacitor,
the method comprising the steps of:
in the rough-adjusting loop part,
storing switching information for the first switching parts in a switching-information storing part;
setting switching information for the first switching parts;
generating a frequency-divided signal by frequency-dividing the oscillating signal of the voltage control oscillator adjusted based on the switching information set by the switching-information setting part for the first switching parts;
instructing the switching-information setting part to set again the switching information based on a result of comparison between a frequency of the frequency-divided signal and a frequency of a reference signal; and
generating differential information between the switching information set by the switching-information setting part and the switching information stored in the switching-information storing part, and informing the loop control part of completion of the rough adjustment if the differential information belongs in a specific threshold range whereas instructing the switching-information setting part of setting again the switching information if the differential information is out of the threshold range, and
in the fine-adjusting loop part:
detecting a phase difference between the frequency-divided signal obtained by frequency-dividing the oscillating signal at the frequency divider and the reference signal while a switched state of each of the first switching parts at a moment of the completion of the rough adjustment at the rough-adjusting loop part remains unchanged;
generating a voltage signal in accordance with the phase difference; and
removing noises included in the voltage signal to generate the control signal for controlling the capacitance of the variable capacitor.

12. The method claimed in claim 11, wherein the differential information is generated when the oscillating-frequency adjusting part has performed frequency adjustment to the frequency-divided signal for a predetermined number of times or when a difference in frequency between the frequency-divided signal and the reference signal becomes equal to or smaller than a predetermined value.

13. The method claimed in claim 11, wherein the completion of the rough adjustment is informed to the loop control part without a search for an optimum frequency for the frequency-divided signal if the differential information belongs in the threshold range.

14. The method claimed in claim 11, wherein the frequency of the frequency-divided signal is again compared with the frequency of the reference signal when the comparator determines that the differential information is out of the threshold range.

15. The method claimed in claim 11, wherein the loop control part selects the rough-adjusting loop part in case of power-on or an initial operation and then determines a timing to operate the fine-adjusting loop part based on information from the oscillating-frequency adjusting part.

16. The method claimed in claim 11, wherein the loop control part exclusively switches the rough- and fine-adjusting loop parts.

17. The method claimed in claim 11 further comprising:
switching by a second switching part, the frequency-divided signal and the reference signal between being supplied to and not being supplied to the oscillating-frequency adjusting part; and
switching by a third switching part, the frequency-divided signal and the reference signal between being supplied to and not being supplied to the phase comparator,
wherein the loop control part performs switching control of the second and third switching parts.

18. The method claimed in claim 11, wherein the fine-adjusting loop part performs the fine adjustment using a switched state of the first switching parts at a moment of the completion of the rough adjustment even if the control signal varies during the fine adjustment.

19. The method claimed in claim 11 further comprising the step of outputting a lock detection signal indicating that the fine-adjusting loop part is in a locked state when the phase difference becomes equal to or smaller than a specific value, wherein the switching-information storing part stores the switching information already set by the switching-information setting part, based on the lock detection signal.

20. The method claimed in claim 11, wherein a plurality of pieces of switching information are provided for the first switching parts so that variable ranges of an oscillating frequency is overlapped to each other between neighboring two or more of the pieces of switching information, and any one of the plurality of pieces of switching information is set.
